(19) United States
(12) Patent Application Publication
(10) Pub. No.: US 2011/0284060 A1
(43) Pub. Date: Nov. 24, 2011

(54) SOLAR CELL AND METHOD OF FABRICATING THE SAME

(76) Inventor: Doo-Youl Lee, Seoul (KR)

(21) Appl. No.: 12/917,104

(22) Filed: Nov. 1, 2010

(30) Foreign Application Priority Data
May 24, 2010 (KR) 10-2010-0048159

(51) Int. Cl. H01L 31/06; H01L 31/0224

(52) U.S. Cl. 136/255; 438/87; 257/E31.124

(57) ABSTRACT

A solar cell and method of fabricating the same using a simplified process. The solar cell includes a semiconductor substrate of a first conductivity type having a front surface configured to receive sunlight and a back surface opposite to the front surface, and a diffusion region of the first conductivity type and a diffusion region of a second conductivity type extending from the back surface of the semiconductor substrate into the semiconductor substrate to a predetermined depth, wherein the diffusion region of the first conductivity type is counter doped with both a dopant of the first conductivity type and a dopant of the second conductivity type.

### CROSS-REFERENCE TO RELATED APPLICATION

This application claims priority from Korean Patent Application No. 10-2010-0048159 filed on May 24, 2010 in the Korean Intellectual Property Office, the disclosure of which is incorporated herein by reference in its entirety.

### BACKGROUND

1. Technical Field

The inventive concept relates to a solar cell and method of fabricating the solar cell, and more particularly, to a solar cell and method of fabricating the solar cell using a simplified process.

2. Discussion of the Related Art

As depletion of existing energy resources such as oil or coal is predicted, increasing attention is being given to alternative energy sources. In particular, solar cells provide electrical energy converted from the abundant and eco-friendly sunlight.

A solar cell includes a silicon substrate with p- and n-type diffusion regions. Upon exposure to radiation of light, electrons and holes are ejected from the silicon substrate. The electrons and holes are attracted to the p- and n-type diffusion regions, respectively, and accumulate in electrodes coupled to the diffusion regions. Electrical current is produced when the electrodes are connected to each other by a wire.

### SUMMARY

Exemplary embodiments of the inventive concept provide a solar cell and method of fabricating the solar cell using a simplified process.

According to an embodiment of the inventive concept, there is provided a solar cell including a semiconductor substrate of a first conductivity type having a front surface that receives sunlight and a back surface opposite to the front surface, and a diffusion region of the first conductivity type and a diffusion region of a second conductivity type extending from the back surface of the semiconductor substrate into the semiconductor substrate to a predetermined depth, wherein the diffusion region of the first conductivity type is counter doped with a dopant of the first conductivity type and a dopant of the second conductivity type.

According to an embodiment of the inventive concept, there is provided a method of fabricating a solar cell including providing a semiconductor substrate of a first conductivity type having a front surface that receives sunlight and a back surface opposite to the front surface, forming an oxide layer on the back surface of the semiconductor substrate, forming a first contact hole within the oxide layer so as to expose a region of the semiconductor substrate, doping the semiconductor substrate with a dopant of the first conductivity type and forming a diffusion region of the first conductivity type within the region of the semiconductor substrate exposed by the first contact hole, forming a second contact hole within the oxide layer so as to expose a region of the semiconductor substrate not exposed by the first contact hole, and counter doping the semiconductor substrate with a dopant of the second conductivity type and forming a diffusion region of the second conductivity type within a region of the semiconductor substrate exposed by the second contact hole.

According to an embodiment of the inventive concept, there is provided a solar cell including a semiconductor substrate of a first conductivity type having a front surface configured to receive sunlight and a back surface opposite to the front surface, and a first diffusion region of the first conductivity type and a second diffusion region of a second conductivity type, the first diffusion region extending from the back surface of the semiconductor substrate toward the front surface by a first predetermined depth, and the second diffusion region extending from the back surface of the semiconductor substrate toward the front surface by a second predetermined depth, wherein the diffusion region of the first conductivity type is counter doped with both a dopant of the first conductivity type and a dopant of the second conductivity type.

### BRIEF DESCRIPTION OF THE DRAWINGS

The embodiments of the inventive concept will become more apparent by describing in detail exemplary embodiments thereof with reference to the attached drawings in which:

FIG. 1 is a cross-sectional view of a solar cell according to an embodiment of the inventive concept; and

FIGS. 2, 3, 4, 5, 6, 7, 8, 9, and 10 are cross-sectional views sequentially illustrating process steps in a method of fabricating a solar cell according to an embodiment of the inventive concept.

### DETAILED DESCRIPTION

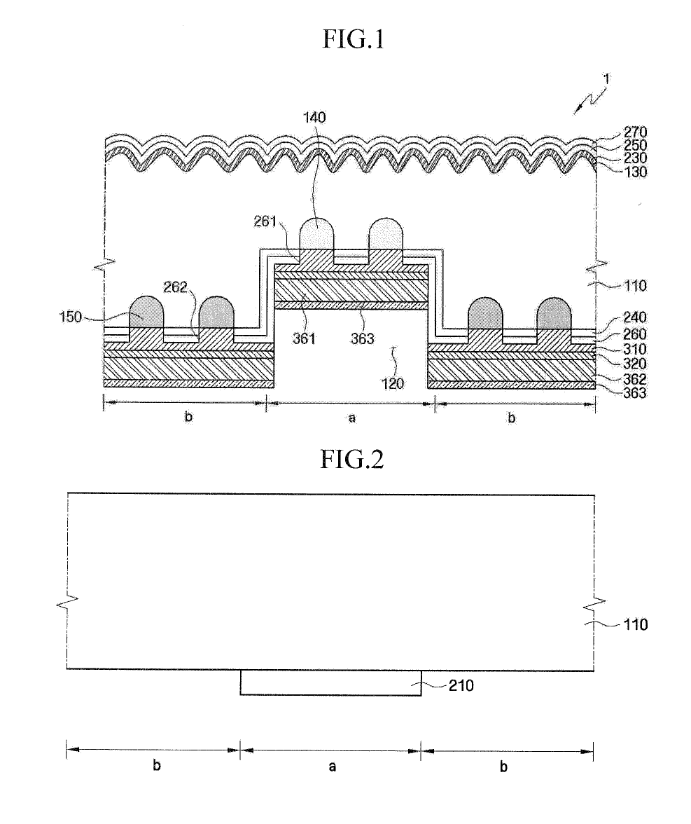

Hereinafter, a solar cell according to an embodiment of the inventive concept will be described in further detail with reference to FIG. 1. It will be understood that when a layer, film, region, or plate is referred to as being “on” or “over” another element or layer, it can be directly on another element or layer or intervening elements or layers may also be present.

FIG. 1 is a cross-sectional view of a solar cell 1 according to an embodiment of the inventive concept.

Referring to FIG. 1, the solar cell 1 includes a semiconductor substrate 110 that may be a monocrystalline silicon wafer or polycrystalline silicon wafer. Alternatively, the semiconductor substrate 110 may include a material other than silicon. The semiconductor substrate 110 acts as a light absorbing layer that absorbs sunlight.

The semiconductor substrate 110 has a front surface that receives sunlight and a back surface opposite to the front surface.

The semiconductor substrate 110 may be doped with a dopant of a first conductivity type. The first conductivity type may be a p-type or an n-type. While it is described in the present embodiment that the semiconductor substrate 110 is a monocrystalline or polycrystalline silicon substrate doped with an n-type dopant, the inventive concept is not limited thereto. A p-type dopant includes an element belonging to the group III in the periodic table of elements, such as boron (B), aluminum (Al), or gallium (Ga), and an n-type dopant includes an element belonging to the group V in the periodic table of elements, such as phosphorous (P) or arsenic (As).

The back surface of the semiconductor substrate 110 has a stepped portion, such as a recess 120. The semiconductor substrate 110 is divided into a first area ‘a’ and a second area ‘b’. While FIG. 1 shows the recess 120 is provided on the first area a, the recess 120 may be formed on the first area a or the second area b. The back surface of the semiconductor substrate 110 is stepped to separate electrodes 361 and 362 formed on the first and second areas a and b, respectively, from each other without using a patterning process.

A first passivation oxide layer 240 and a capping oxide layer 260 are sequentially formed on the back surface of the semiconductor substrate 110 and have first and second contact holes 261 and 262 therein which expose portions of the back surface of the semiconductor substrate 110. The first and second contact holes 261 and 262 are formed on the first area a and the second area b, respectively.

A diffusion region 140 of a first conductivity type (e.g., n-type) is formed within a region of the semiconductor substrate 110 exposed by the first contact hole 261 and extends inward from the back surface of the semiconductor substrate 110 to a predetermined depth. A diffusion region 150 of a second conductivity type (e.g., p-type) is formed within a region of the semiconductor substrate 110 exposed by the second contact hole 262 and extends inward from the back surface of the semiconductor substrate 110 to a predetermined depth. The diffusion regions 140 and 150 are self-aligned with the first and second contact holes 261 and 262, respectively.

The diffusion region 140 of the first conductivity type is counter doped with dopants having the first and second conductivity types.

According to an embodiment, after forming the diffusion region 140 of the first conductivity type in a self-aligned manner by using the first contact hole 261, the diffusion region 150 of the second conductivity type is formed in a self-aligned manner by using the second contact hole 262 without masking the diffusion region 140.

A dopant of the second conductivity type is counter doped into the diffusion region 140 of the first conductivity type. A dopant source of the first conductivity type selected may have a significantly higher solid solubility than a dopant source of the second conductivity type within the semiconductor substrate 110. Thus, since the dopant of the first conductivity type has a higher concentration than the dopant of the second conductivity type within the diffusion region 140 of the first conductivity type, the diffusion region 140 of the first conductivity type can maintain the first conductivity type despite being counter doped with the dopant of the second conductivity type.

To maintain the first conductivity type in the diffusion region 140, the concentration of the dopant source of the second conductivity type may be made higher than that of the dopant of the first conductivity type in the semiconductor substrate 110 but lower than that of the dopant of the first conductivity type in the diffusion region 140 of the first conductivity type. The region of the semiconductor substrate 110 exposed by the second contact hole 262 is counter doped with the dopant of the second conductivity type to change the first conductivity type into the second conductivity type and form the diffusion region 150 of the second conductivity type.

First and second electrodes 361 and 362 are disposed on the back surface of the semiconductor substrate 110 and electrically coupled to the diffusion region 140 of the first conductivity type and the diffusion region 150 of the second conductivity type, respectively. The first electrode 361 is disposed within the recess 120 and the second electrode 362 is disposed on the back surface of the semiconductor substrate 110 excluding the recess 120. The first and second electrodes 361 and 362 may include a layer containing copper (Cu).

An ohmic layer 310 and a barrier layer 320 may be sequentially disposed between the diffusion region 140 of the first conductivity type and the first electrode 361 and between the diffusion region 150 of the second conductivity type and the second electrode 362. The ohmic layer 310 may contain aluminum (Al), and the barrier layer 320 may contain titanium tungsten (TiW), chrome (Cr) or nickel (Ni).

The ohmic layer 310 and the barrier layer 320 are disconnected by the recess 120 on a boundary between the first area a and the second area b, thus electrically separating the first and second electrodes 361 and 362 from each other.

A metal layer 363 for soldering may be formed on the first and second electrodes 361 and 362. The metal layer 363 contains tin (Sn).

The front surface of the semiconductor substrate 110 has an uneven pattern 130. The uneven pattern 130 can increase the area that can absorb sunlight and the length of a path along which light travels, thus increasing the number of electron hole pairs (EHPs) generated by sunlight.

For example, the uneven pattern 130 may be a quadrangular prism pattern or inverted quadrangular pattern. However, the uneven pattern 130 is not limited thereto, and may have various shapes such as triangular pyramids, pentagonal pyramids, polygonal pyramids having more faces than the pentagonal pyramids, cones, polygonal prisms, and cylinders. Further, the front surface of the semiconductor substrate 110 may have various shapes adapted to increase the surface area and/or improve light absorption efficiency.

A field forming layer 230 is formed on the uneven pattern 130. The field forming layer 230 may be doped with a dopant of the first conductivity type (e.g., n-type).

A second passivation oxide layer 250 is formed on the field forming layer 230. The second passivation oxide layer 250 may be formed of silicon oxide (SiO₂). The field forming layer 230 and the second passivation oxide layer 250 can minimize the recombination of electrons and holes generated by sunlight.

An anti-reflection layer 270 is formed on the second passivation oxide layer 250. The anti-reflection layer 270 may be formed of silicon nitride (SiNx) or titanium oxide (TiO₂) to reduce the reflection of sunlight incident on the front surface of the solar cell 1 as much as possible.

Hereinafter, a method of fabricating the solar cell 1 according to an embodiment of the inventive concept will be described in more detail with reference to FIGS. 2, 3, 4, 5, 6, 7, 8, 9, and 10 together with FIG. 1. FIGS. 2, 3, 4, 5, 6, 7, 8, 9, and 10 are cross-sectional views sequentially illustrating process steps in the method of fabricating the solar cell 1 according to an embodiment of the inventive concept.

Referring to FIG. 2, a semiconductor substrate 110 has a first area a where the diffusion region of the first conductivity type (140 of FIG. 1) will be formed and a second area b where the diffusion region of the second conductivity type (150 of FIG. 1) will be formed. For example, the semiconductor substrate 110 may be a substrate of the first conductivity type (e.g., n-type) doped with a dopant of the first conductivity type.

First, an etching paste 210 is applied on the back surface of the semiconductor substrate 110 at one of the first area a and the second area b (e.g., the first area a) using spin coating, slit coating, spraying, screen printing, inkjet printing, gravure printing, offset printing, or dispensing.

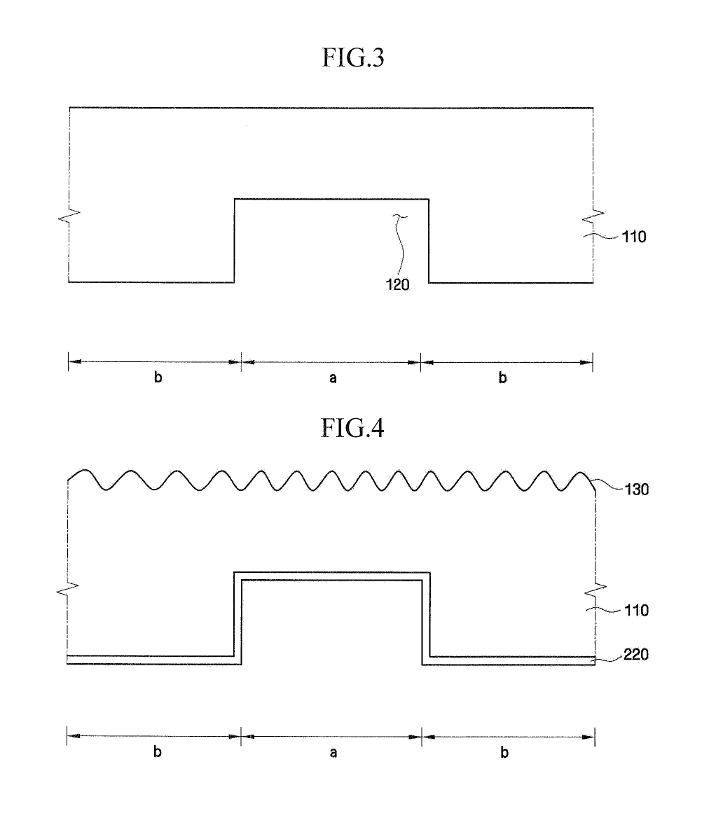

Referring to FIG. 3, the first area a of the semiconductor substrate 110 is then etched to a predetermined depth from the back surface, thereby forming a recess 120 at the first area a. The recess 120 may have a depth sufficient to isolate the first electrode (361 of FIG. 1) that will be formed at the first area a from the second electrode (362 of FIG. 1) that will be formed at the second area b when forming electrodes on the back surface of the semiconductor substrate 110. After forming the recess 120, the etching paste 210 is removed.

While the recess 120 is formed by etching using the etching paste 210, the recess 120 may be formed using other techniques such as photolithography, laser patterning using line-type laser, or nano-imprinting using a replica.

Next, referring to FIG. 4, a cover oxide layer 220 is formed on the back surface of the semiconductor substrate 110 to protect the back surface of semiconductor substrate 110 during the subsequent process. The cover oxide layer 220 may be formed by sputtering using SiO₂ as a target material or plasma enhanced chemical vapor deposition (PECVD).

Subsequently, the uneven pattern 130 is formed on the front surface of the semiconductor substrate 110. The uneven pattern 130 may be formed by etching the front surface of the semiconductor substrate 110. According to an embodiment, dry etching or wet etching may be used.

If the uneven pattern 130 is formed by wet etching, the semiconductor substrate 110 may be exposed to an alkaline etching solution such as tetramethy hydroxide ammonium (TMHA), potassium hydroxide (KOH), or sodium hydroxide (NaOH), to which materials such as isopropyl alcohol (IPA) and isopropyl ethanol (IPE) are added.

Referring to FIG. 5, a field forming layer 230 is formed on the uneven pattern 130. The field forming layer 230 contains a dopant of the first conductivity type (e.g. n-type). The field forming layer 230 creates a high-low junction on the surface of the semiconductor substrate 110 to enhance passivation. An electric field is created at the high-low junction and repels the minority carries from electrodes, thereby reducing surface recombination.

The field forming layer 230 may be formed by introducing a dopant source into a furnace and performing annealing. When the first conductivity type is an n-type, the dopant source used to form the field forming layer 230 may be one of phosphorus chloride oxide (POCl₃), phosphoric acid (H₃PO₄, P₂PO₅, or P₂PO₇) and phosphorus trihydride (PH₃). When the first conductivity type is a p-type, the dopant source may be boron nitride (BN), glass ceramic boron, or diborane (B₂H₆).

When the dopant source is POCl₃, as shown in FIG. 5, a phosphorus silicate glass (PSG) layer 231 may be formed simultaneously with the field forming layer 230.

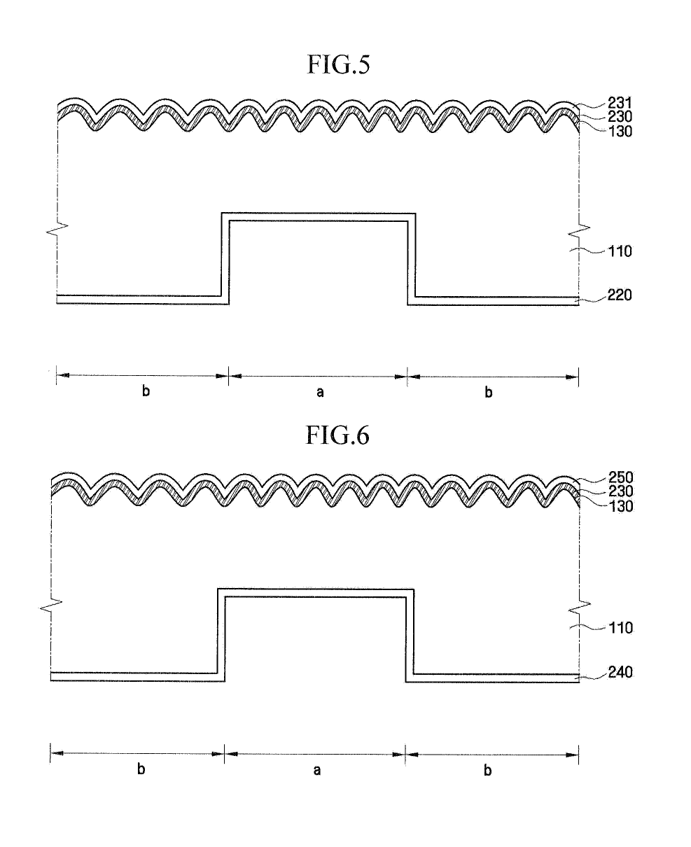

Referring to FIG. 6, the cover oxide layer 220 and the PSG layer 231 are then removed to form the first and second passivation oxide layers 240 and 250 on the back surface of the semiconductor substrate 110 and the field forming layer 230 overlying the front surface thereof, respectively.

The first and second passivation oxide layers 240 and 250 may be formed by clean oxidation in which an oxide layer is formed with a predetermined flow rate of oxygen (O₂) and hydrochloric acid (HCl). More specifically, when a mixture of O₂ and HCl is introduced into the semiconductor substrate 110, metallic contaminants can be removed by chorine (Cl) in HCl from the surface of the semiconductor substrate 110 to form a clean oxide layer.

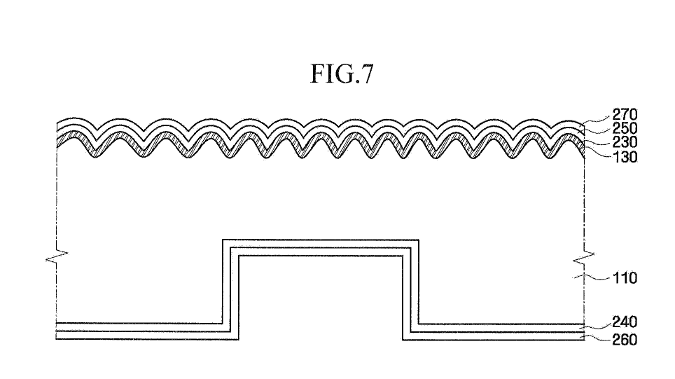

Referring to FIG. 7, an anti-reflection layer 270 is formed on the second passivation oxide layer 250. The anti-reflection layer 270 may be formed of SiNx or TiO₂ by using PECVD.

Then, a capping oxide layer 260 is formed on the first passivation oxide layer 240. The capping oxide layer 260 may be formed by a technique such as sputtering using SiO₂ as a target material or PECVD.

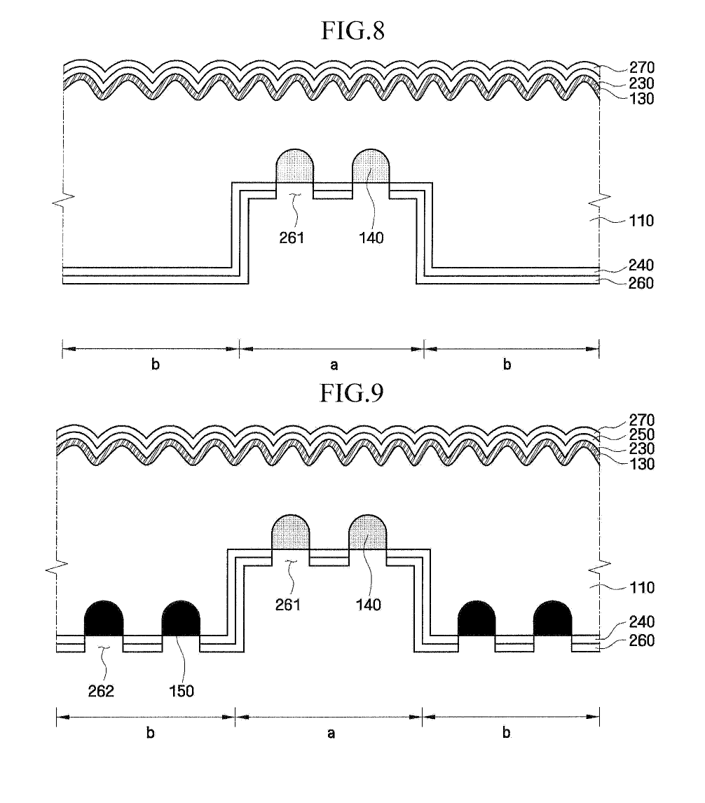

Referring to FIG. 8, portions of the first passivation oxide layer 240 and capping layer 260 formed on the back surface of the semiconductor substrate 110 at one of the first area a and the second area b (e.g., the first area a) are removed to form a first contact hole 261. The first contact hole 261 may be formed by laser patterning using line-type laser. Thus, photolithography is not needed for forming the first contact hole 261, thereby simplifying the overall process.

Subsequently, a diffusion region 140 of the first conductivity type (e.g., n-type) is formed within a region of the semiconductor substrate 110 exposed by the first contact hole 261. The diffusion region 140 of the first conductivity type may be formed by doping the semiconductor substrate 110 with a dopant of the first conductivity type. The diffusion region 140 of the first conductivity type is formed within the region of the semiconductor substrate in self-alignment with the first contact hole 261.

When the first conductivity type is an n-type, a dopant source may be one of POCl₃, H₃PO₄, P₂PO₅, P₂PO₇, and PH₃. The semiconductor substrate 110 may be doped with the dopant of the first conductivity type using ion implantation. More specifically, the ion implantation includes introducing the dopant of the first conductivity type into the semiconductor substrate 110 and annealing the semiconductor substrate 110.

Referring to FIG. 9, portions of the first passivation oxide layer 240 and capping layer 260 formed on the back surface of the semiconductor substrate 110 at the other one of the first area a and the second area b (e.g., the second area b) are removed to form a second contact hole 262. The second contact hole 262 may be formed by laser patterning using line-type laser. Thus, photolithography is not needed for forming the second contact hole 262, thereby simplifying the overall process.

Thereafter, a diffusion region 150 of the second conductivity type (e.g., p-type) is formed in a region of the semiconductor substrate 110 exposed by the second contact hole 262. The diffusion region 150 of the second conductivity type may be formed by counter doping the semiconductor substrate 110 with a dopant of the second conductivity type. When the concentration of the dopant of the second conductivity type is made higher than that of the dopant of the first conductivity type in the semiconductor substrate 110 but lower than that of the dopant of the first conductivity type in the diffusion region 140, the diffusion region 140 of the first conductivity type maintains the first conductivity type, and the region of the semiconductor substrate 110 exposed by the second contact hole 262 is changed into a region of the second conductivity type. Thereby, the diffusion region 150 of the second conductivity type is formed in a self-alignment with the second contact hole 262.

When the first conductivity type is a p-type, a dopant source may be boron fluoride (BF₂), BN, glass ceramic boron, or B₂H₆. The semiconductor substrate 110 may be counter doped with the dopant of the second conductivity type using ion implantation that includes introducing the dopant of the second conductivity type into the semiconductor substrate 110 and annealing the semiconductor substrate 110.

Referring to FIGS. 8 and 9, according to an present embodiment, after forming the diffusion region 140 of the first conductivity type in self-alignment with the first contact hole 261, the semiconductor substrate 110 in which the second contact hole 262 is formed is counter doped with the dopant source of the second conductivity type without masking the diffusion region 140 to form the diffusion region 150 of the second conductivity type in self-alignment with the second contact hole 262. According to an embodiment, a doping process for forming the diffusion regions 140 and 150 is performed without separate masking. Thus, the fabrication process can be simplified.

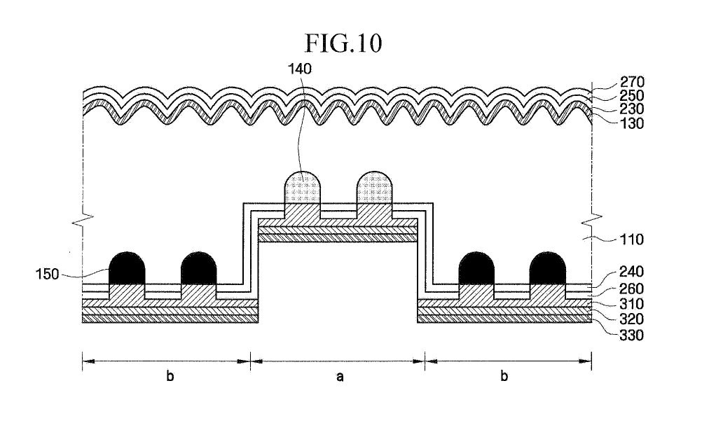

Referring to FIG. 10, an ohmic layer 310, a barrier layer 320, and a seed material layer 330 are sequentially formed on the back surface of the semiconductor substrate 110. For example, the ohmic layer 310 may contain Al. The barrier layer 320 may contain TiW, Cr, or Ni. The seed material layer 330 may contain Cu. The ohmic layer 310, the barrier layer 320, and the seed material layer 330 may be formed by using a technique such as sputtering or thermal evaporation.

Referring again to FIG. 1, following the formation of the ohmic layer 310, the barrier layer 320, and the seed material layer 330, first and second electrodes 361 and 362 are disposed on the barrier layer 320 and electrically connected to the diffusion region 140 of the first conductivity type and the diffusion region 150 of the second conductivity type, respectively. The first and second electrodes 361 and 362 may be formed by increasing the thickness of the seed material layer 330 using electroplating or electroless plating. For example, the first and second electrodes 361 and 362 may be formed by using a plating solution containing Cu.

A metal layer 363 for soldering may be formed on the first and second electrodes 361 and 362 by electroplating or electroless plating using a plating solution containing Sn.

To reduce contact resistance at the interface between the semiconductor substrate 110 and the ohmic layer 310, the semiconductor substrate 110 may be annealed in hydrogen atmosphere. The annealing may also reduce the dangling bond or SiO₂ to remove an insulating layer.

Referring to FIGS. 1 and 10, the seed material layer 330 is discontinuously formed at a boundary between the first area a and the second area b by the recess 120 formed in the back surface of the semiconductor substrate 110. Thus, the first and second electrodes 361 and 362 formed of the seed material layer 330 are also disconnected from each other. This eliminates the need to perform a photolithography process for separating portions of the ohmic layer 310 and barrier layer 320 and the first electrode 361 formed at the first area a from the remaining portions of the ohmic layer 310 and barrier layer 320 and the second electrode 362 formed at the second area b, thereby simplifying the fabrication process.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the present embodiments be considered in all respects as illustrative and not restrictive, reference being made to the appended claims rather than the foregoing description to indicate the scope of the invention.

What is claimed is:

1. A solar cell comprising:
a semiconductor substrate of a first conductivity type having a front surface configured to receive sunlight and a back surface opposite to the front surface, and
a diffusion region of the first conductivity type and a diffusion region of a second conductivity type extending from the back surface of the semiconductor substrate into the semiconductor substrate to a predetermined depth,
wherein the diffusion region of the first conductivity type is counter doped with both a dopant of the first conductivity type and a dopant of the second conductivity type.

2. The solar cell of claim 1, wherein the dopant of the first conductivity type has a higher concentration than the dopant of the second conductivity type within the diffusion region of the first conductivity type.

3. The solar cell of claim 2, wherein a concentration of the dopant of the second conductivity within the diffusion region of the second conductivity type is higher than a concentration of the dopant of the first conductivity type within the semiconductor substrate and lower than a concentration of the dopant of the first conductivity type within the diffusion region of the first conductivity type.

4. The solar cell of claim 3, wherein the first conductivity type is an n-type and the second conductivity type is a p-type.

5. The solar cell of claim 1, further comprising an oxide layer formed on the back surface of the semiconductor substrate and having first and second contact holes therein which respectively expose the diffusion region of the first conductivity type and the diffusion region of the second conductivity type.

6. The solar cell of claim 5, wherein the diffusion region of the first conductivity type is self-aligned by the first contact hole and the diffusion region of the second conductivity type is self-aligned by the second contact hole.

7. The solar cell of claim 1, wherein the back surface of the semiconductor substrate has a recess.

8. The solar cell of claim 7, wherein the diffusion region of the first conductivity type is formed to correspond to an area of the semiconductor substrate where the recess is formed and the diffusion region of the second conductivity type is formed to correspond to an area of the semiconductor substrate where the recess is not formed.

9. The solar cell of claim 8, further comprising first and second electrodes formed on the back surface of the semiconductor substrate and electrically connected to the diffusion region of the first conductivity type and the diffusion region of the second conductivity type, respectively.

10. The solar cell of claim 9, wherein the first electrode is formed within the recess and the second electrode is formed on the back surface of the semiconductor substrate excluding the recess, so that the first and second electrodes are electrically isolated from each other by the recess.

11. A method of fabricating a solar cell, comprising:
providing a semiconductor substrate of a first conductivity type having a front surface that receives sunlight and a back surface opposite to the front surface;
forming an oxide layer on the back surface of the semiconductor substrate;
forming a first contact hole within the oxide layer to expose a region of the semiconductor substrate;
doping the semiconductor substrate with a dopant of the first conductivity type and forming a diffusion region of the first conductivity type within the region of the semiconductor substrate exposed by the first contact hole;
forming a second contact hole within the oxide layer to expose a region of the semiconductor substrate not exposed by the first contact hole; and
counter doping the semiconductor substrate with a dopant of the second conductivity type and forming a diffusion region of the second conductivity type within the region of the semiconductor substrate exposed by the second contact hole.

12. The method of claim 11, wherein a concentration of the dopant of the second conductivity within the diffusion region of the second conductivity type is higher than a concentration of the dopant of the first conductivity type within the semiconductor substrate and lower than a concentration of the dopant of the first conductivity type within the diffusion region of the first conductivity type.

13. The method of claim 12, wherein the first conductivity type is an n-type and the second conductivity type is a p-type.

14. The method of claim 11, wherein the diffusion region of the first conductivity type is self-aligned by the first contact hole and the diffusion region of the second conductivity type is self-aligned by the second contact hole.

15. The method of claim 11, wherein the diffusion region of the first conductivity type and the diffusion region of the second conductivity type are formed using ion implantation.

16. The method of claim 11, further comprising forming a recess in the back surface of the semiconductor substrate.

17. The method of claim 16, wherein the formation of the recess is performed by patterning using etching paste, photolithography, laser patterning using line-type laser, or nano-imprinting using a replica.

18. The method of claim 16, wherein the diffusion region of the first conductivity type is formed to correspond to an area of the semiconductor substrate where the recess is formed and the diffusion region of the second conductivity type is formed to correspond to an area of the semiconductor substrate where the recess is not formed.

19. The method of claim 16, further comprising forming electrodes on the back surface of the semiconductor substrate, wherein the electrodes are electrically disconnected from each other by the recess.

20. The method of claim 11, wherein the first and second contact holes are formed by irradiating laser into the oxide layer and removing a predetermined portion of the oxide layer.

21. A solar cell comprising:
a semiconductor substrate of a first conductivity type having a front surface configured to receive sunlight and a back surface opposite to the front surface, and
a first diffusion region of the first conductivity type and a second diffusion region of a second conductivity type, the first diffusion region extending from the back surface of the semiconductor substrate toward the front surface by a first predetermined depth, and the second diffusion region extending from the back surface of the semiconductor substrate toward the front surface by a second predetermined depth,
wherein the diffusion region of the first conductivity type is counter doped with both a dopant of the first conductivity type and a dopant of the second conductivity type.

22. The solar cell of claim 21, wherein the front surface has an uneven pattern and the back surface has a recess.
